(19) United States
(12) Patent Application Publication
(10) Pub. No.: US 2024/0379392 A1
(43) Pub. Date: Nov. 14, 2024

(54) PROCESSING SYSTEM AND TEACHING METHOD

(71) Applicant: Tokyo Electron Limited, Tokyo (JP)

(72) Inventor: Toshiaki TOYOMAKI, Miyagi (JP)

(73) Assignee: Tokyo Electron Limited, Tokyo (JP)

(21) Appl. No.: 18/657,802

(22) Filed: May 8, 2024

(30) Foreign Application Priority Data
May 8, 2023 (JP) 2023-076821

(51) Int. Cl. H01L 21/67; H01L 21/687

(52) U.S. Cl. CPC H01L 21/67259; H01L 21/67201; H01L 21/68707

(57) ABSTRACT

Provided is a processing system comprising: a transfer module having therein a transfer device configured to transfer an object to be transferred; a plurality of load-lock modules connected to the transfer module, each having therein a support; a detection part disposed in the transfer device and the plurality of load-lock modules and detecting an object; and a controller configured to process a detection result and control an operation of the transfer device, wherein the controller controls: (A) acquiring information on positions of the supports in the plurality of load-lock modules from a detection result of the object detected by the detection part; and (B) calculating, after said (A), tilt angles of the plurality of load-lock modules with respect to the transfer module based on the acquired information on the positions of the plurality of supports, and setting the positions of the plurality of supports using the calculated tilt angles.

### CROSS-REFERENCE TO RELATED APPLICATION

This application claims priority to Japanese Patent Application No. 2023-076821 filed on May 8, 2023, the entire contents of which are incorporated herein by reference.

### TECHNICAL FIELD

The present disclosure relates to a processing system and a teaching method.

### BACKGROUND

Japanese Laid-open Patent Publication No. 2022-104042 discloses a processing system (substrate processing apparatus) that includes an atmospheric transfer module (loader module), a plurality of load-lock modules, a vacuum transfer module, and a plurality of substrate processing modules, and processes a substrate. A transfer device (wafer transfer mechanism) of the atmospheric transfer module takes out a substrate from a load port disposed in the atmospheric transfer module, and transfers the substrate to an appropriate load-lock module via the atmospheric transfer module.

In such a processing system, in order to improve the transfer accuracy of a substrate, which is an object to be transferred, during installation or maintenance of the system, an operation of teaching a substrate transfer position to a transfer device is performed.

### SUMMARY

The present disclosure provides a technique capable of improving the transfer accuracy of an object to be transferred.

In accordance with an aspect of the present disclosure, there is provided a processing system comprising: a transfer module having therein a transfer device configured to transfer an object to be transferred; a plurality of load-lock modules connected to the transfer module, each having therein a support that supports the object to be transferred; a detection part disposed in the transfer device and the plurality of load-lock modules and detecting an object during movement of the transfer device; and a controller configured to process a detection result obtained by the detection part and control an operation of the transfer device, wherein the controller controls: (A) acquiring information on positions of the supports in the plurality of load-lock modules from a detection result of the object detected by the detection part while moving the transfer device; and (B) calculating, after said (A), tilt angles of the plurality of load-lock modules with respect to the transfer module based on the acquired information on the positions of the plurality of supports, and setting the positions of the plurality of supports using the calculated tilt angles.

### BRIEF DESCRIPTION OF THE DRAWINGS

FIG. 1 is a plan view schematically showing a processing system according to an embodiment.

FIG. 2 is a side cross-sectional view partially showing a load-lock module and an atmospheric transfer module.

FIG. 3 is an explanatory diagram showing an example of a hardware configuration of a controller.

FIG. 4 shows an example of a schematic configuration of a pick.

FIG. 5A is a flowchart illustrating a method for teaching an atmospheric transfer device according to an embodiment.

FIG. 5B is a flowchart showing an example of a first teaching step.

FIG. 5C is a flowchart showing an example of a second teaching step.

FIG. 6 is an explanatory diagram showing an operation in a first detection step.

FIG. 7 is an explanatory diagram showing an operation of an atmospheric transfer device in a second detection step.

FIG. 8 is a plan view illustrating an installation state in which each load-lock module is tilted with respect to an atmospheric transfer module.

FIG. 9 is an explanatory diagram showing an operation of a vacuum transfer device in an installation step.

FIGS. 10A to 10D explain an example of a horizontal direction setting step.

FIG. 11 is a flowchart for explaining a vertical direction setting step for determining a vertical transfer position.

### DETAILED DESCRIPTION

Hereinafter, embodiments of the present disclosure will be described in detail with reference to the accompanying drawings. Like reference numerals will be given to like or corresponding parts throughout the drawings, and redundant description thereof may be omitted.

### (Processing System)

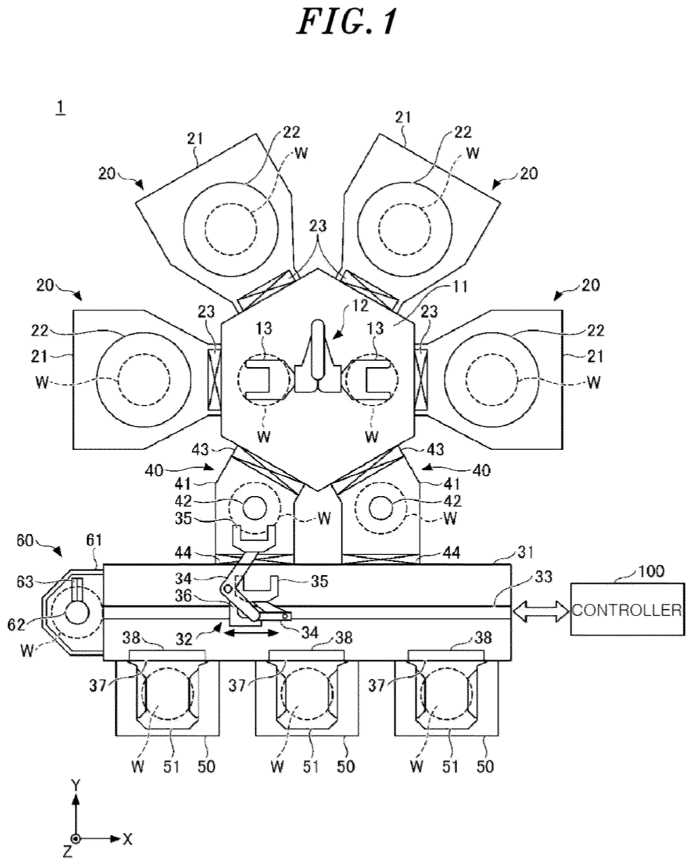

A processing system 1 according to an embodiment will be described with reference to FIG. 1. FIG. 1 is a plan view schematically showing the processing system 1 according to an embodiment. The processing system 1 is an apparatus that is used in one process of manufacturing semiconductor substrates. The processing system 1 transfers a substrate as an object to be transferred and performs substrate treatment on the substrate. The substrate subjected to substrate treatment may be a silicon semiconductor wafer, a compound semiconductor wafer, an oxide semiconductor wafer, or the like. Hereinafter, the substrate will be also referred to as “wafer W.” The wafer W may have a pattern of a recess such as a trench, a via, or the like.

Specifically, the processing system 1 includes a vacuum transfer module 10, a plurality of processing modules 20, an atmospheric transfer module 30, a plurality of load-lock modules 40, and a controller 100.

The vacuum transfer module 10 has a vacuum transfer chamber 11 that is approximately hexagonal in plan view. A pressure in the vacuum transfer chamber 11 can be reduced to a vacuum atmosphere by an inner pressure adjusting mechanism (not shown). In the processing system 1, the plurality of processing modules 20 and the plurality of load-lock modules 40 are connected to a plurality of sides of the vacuum transfer chamber 11.

The vacuum transfer module 10 has a vacuum transfer device 12 in the vacuum transfer chamber 11. The vacuum transfer device 12 is configured as a multi-joint arm that can be extended/contracted, moved up and down, and rotated, and is configured to access each processing module 20 and each load-lock module 40. The vacuum transfer device 12 has two picks 13 that can operate independently, and can hold and transfer two wafers W at the same time. The vacuum transfer device 12 may adopt various configurations, e.g., a configuration including one pick 13, as long as it can transfer the wafer W between each processing module 20 and each load-lock module 40.

The plurality of processing modules 20 are arranged radially around the vacuum transfer module 10. Although FIG. 1 shows the processing system 1 including four processing modules 20, the number of the processing modules 20 is not limited thereto. Each processing module 20 has a processing chamber 21 that can be depressurized to a vacuum atmosphere. A disc-shaped placing table 22 on which the wafer W is placed is disposed in the processing chamber 21. The vacuum transfer module 10 and the processing module 20 are partitioned by a gate valve 23 that can be opened and closed.

Each processing module 20 performs various substrate treatments on the wafer W placed on the placing table 22. The substrate treatments performed by each processing module 20 includes film formation, etching, heat treatment, ashing, cleaning, or the like. Some or all of the processing modules 20 may be a plasma processing module that performs plasma processing. Further, each of the processing modules 20 may perform different substrate treatments, or may perform the same substrate treatment.

The atmospheric transfer module 30 is connected to the vacuum transfer module 10 via the load-lock modules 40. The atmospheric transfer module 30 has a substantially rectangular parallelepiped atmospheric transfer chamber 31 maintained in an atmospheric pressure atmosphere.

The atmospheric transfer module 30 has an atmospheric transfer device 32 in the atmospheric transfer module 30. For example, the atmospheric transfer device 32 is slidably supported on a guide rail 33 extending along the long side in the atmospheric transfer chamber 31. The atmospheric transfer device 32 has a built-in linear motor (not shown) having an encoder, and moves on the guide rail 33 under the driving of the linear motor. The atmospheric transfer device 32 transfers the wafer W between each load-lock module 40, a substrate storage container 51 and an aligner 60, which will be described later.

The atmospheric transfer device 32 has two multi-joint arms 34 arranged at two horizontal stages. A pick 35 for holding a wafer W is attached to the tip end of each multi-joint arm 34. In the atmospheric transfer device 32, the multi-joint arms 34 can be independently extended/contracted and moved up and down. Further, the multi-joint arms 34 are coaxially connected to a base 36, and rotate integrally in the rotation direction of the base 36. Further, the atmospheric transfer device 32 can adopt various configurations, e.g., a configuration including one pick 35, as long as it can transfer the wafer W between the load-lock module 40, the substrate storage container 51, and the aligner 60.

In the processing system 1, two load-lock modules 40 are connected side by side to one side surface along the long side (X-axis direction) of the atmospheric transfer chamber 31. Further, the processing system 1 includes, on the other side surface along the long side of the atmospheric transfer chamber 31, one or more transfer ports 37 for loading/unloading the wafer W, and one or more opening/closing doors 38 that can open and close the one or more transfer ports 37. In FIG. 1, a configuration including three transfer ports 37 and three opening/closing doors 38 is illustrated.

The atmospheric transfer module 30 has a load port 50 at a position corresponding to each transfer port 37. The substrate storage container 51 that can be transferred while accommodating therein the wafer W is placed on the load port 50. The substrate storage container 51 may be a front-opening unified pod (FOUP) that accommodates a plurality of (e.g., 25) wafers W at predetermined intervals. Further, each load port 50 is provided with a driving mechanism (not shown) for the opening/closing door 38.

In the atmospheric transfer module 30, an aligner 60 is installed on one of two short sides of the atmospheric transfer chamber 31. The aligner 60 and the atmospheric transfer device 32 align the wafer W in the atmospheric transfer module 30. The aligner 60 includes a housing 61, a rotation stage 62 disposed in the housing 61 and rotated by a driving motor (not shown), and an optical sensor 63 disposed in the housing 61 to optically detect the outer edge of the wafer W.

The housing 61 is opened toward the atmospheric transfer chamber 31, and the atmospheric transfer device 32 can access the inside of the housing 61. The rotation stage 62 has a diameter smaller than that of the wafer W, and the center of the wafer W is placed on the upper surface of the rotation stage 62. Further, the aligner 60 uses the optical sensor 63 to detect the notch or the deviation of the outer edge of the wafer W rotated by the rotation stage 62, and calculates the orientation or the positional deviation of the wafer W. When the atmospheric transfer device 32 receives the wafer W from the aligner 60, the wafer W of which orientation or the positional deviation has been corrected by the controller 100 is received.

The two load-lock modules 40 are installed between the vacuum transfer module 10 and the atmospheric transfer module 30, and allow the wafer W to be transferred between the vacuum transfer module 10 and the atmospheric transfer module 30. Further, the number of the load-lock modules 40 in the processing system 1 is not limited to two, and may be three or more.

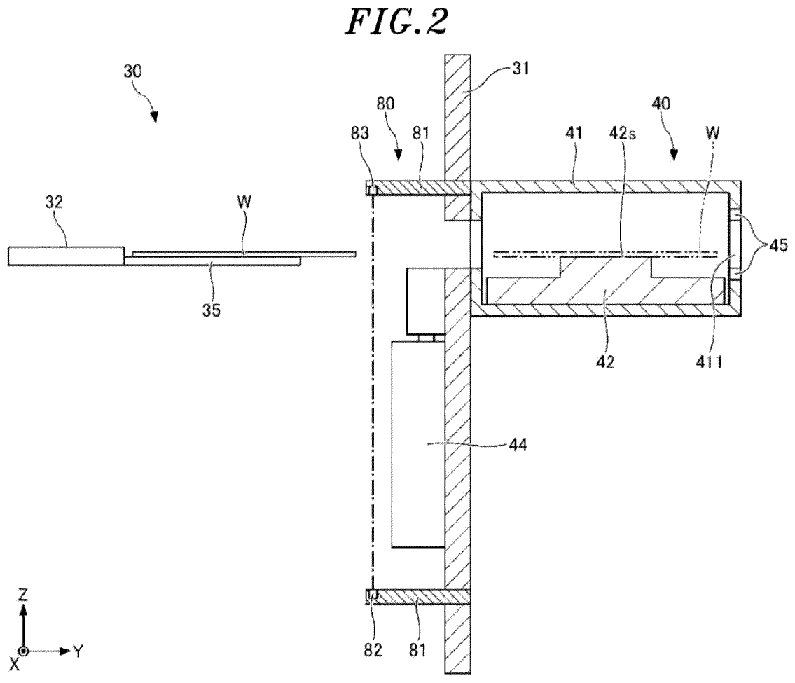

FIG. 2 is a side cross-sectional view partially showing the load-lock module and the atmospheric transfer module 30. As shown in FIG. 2, each load-lock module 40 includes an inner pressure variable chamber 41 of which inner atmosphere can be switched between a vacuum atmosphere and an atmospheric pressure atmosphere, and a stage (support) 42 on which a wafer W can be placed in the inner pressure variable chamber 41. Each load-lock module 40 and vacuum transfer module 10 are partitioned by a gate valve 43 that can be opened and closed (see FIG. 1). Further, each load-lock module 40 and the atmospheric transfer module 30 are partitioned by a gate valve 44 that can be opened and closed. The gate valve 44 is accommodated in the atmospheric transfer chamber 31 of the atmospheric transfer module 30. Further, the processing system 1 may include a dedicated opening/closing module (not shown) accommodating the gate valve 44 between the atmospheric transfer module 30 and each load-lock module 40.

The inner pressure variable chamber 41 has a position detection sensor 45 at the transfer port 411 disposed on the vacuum transfer module 10 side. For example, two position detection sensors 45 are disposed along the horizontal direction (X-axis direction) of the transfer port 411, and detect two positions of the outer edge of the wafer W passing through the transfer port 411 of the load-lock module 40. The controller 100 can calculate the position of the wafer W based on the two detected positions of the outer edge of the wafer W, and can recognize the deviation of the wafer W with respect to the vacuum transfer device 12.

The stage 42 of each load-lock module 40 has a substrate supporting surface 42s having a diameter smaller than that of the wafer W. The vacuum transfer device 12 and the atmospheric transfer device 32 move to a position above the substrate supporting surface 42s in the inner pressure variable chamber 41, and then are lowered vertically downward and pass through the substrate supporting surface 42s, thereby placing the wafer W on the substrate supporting surface 42s. Further, the stage 42 may have a groove corresponding to the shape of the picks 13 and 35, and the picks 13 and 35 may enter the groove. Further, the stage 42 may be provided with a plurality of support pins capable of moving up and down, and may be configured to deliver the wafer W by raising the support pins when the vacuum transfer device 12 or the atmospheric transfer device 32 enters.

In the case of loading the wafer W from the atmospheric transfer module to the vacuum transfer module 10, the wafer W is transferred from the atmospheric transfer module 30 into the load-lock module 40 in a state where the inner pressure variable chamber 41 is maintained in an atmospheric pressure atmosphere. Thereafter, the pressure in the inner pressure variable chamber 41 is depressurized to a vacuum atmosphere, and the wafer W can be loaded into the vacuum transfer module 10. Further, in the case of unloading the wafer W from the vacuum transfer module 10 to the atmosphere transfer module 30, the wafer W is transferred from the vacuum transfer module 10 into the load-lock module 40 in a state where the inner pressure variable chamber 41 is maintained in a vacuum atmosphere. Thereafter, the pressure in the inner pressure variable chamber 41 is increased to an atmospheric pressure atmosphere, and the wafer W can be loaded into the atmospheric transfer module 30.

The processing system 1 includes an object detection sensor (detection part: second detection sensor) 80 at the connection position with each load-lock module 40 in the atmosphere transfer chamber 31 of the atmosphere transfer module 30. In other words, each of the load-lock modules 40 is provided with the object detection sensor 80 disposed in the atmospheric transfer chamber 31. For example, the object detection sensor 80 detects whether or not the wafer W placed on the stage 42 in the load-lock module 40 projects, and transmits the detection result to the controller 100.

Each object detection sensor 80 has protrusions 81 spaced apart from each other in a vertical direction in the atmospheric transfer chamber 31. Each protrusion 81 protrudes in a direction extending radially outward from the center of the stage 42 of the load-lock module 40. For example, each protrusion 81 is connected to the wall of the inner pressure variable chamber 41, and is attached integrally with the inner pressure variable chamber 41. Each object detection sensor 80 has a light transmitting element 82 at one protrusion 81 and a light receiving element 83 at the other protrusion 81. The protrusions 81 protrude inward from the gate valve 44 in the atmospheric transfer chamber 31, thereby making the light emitting element 82 and the light receiving element 83 face each other.

For example, the light transmitting element 82 is disposed below the gate valve 44, and emits detection light toward the light receiving element 83. The light receiving element 83 is disposed above the gate valve 44, and receives the detection light emitted by the light transmitting element 82. The positional relationship between the light transmitting element 82 and the light receiving element 83 may be reversed.

When the wafer W placed on the stage 42 of the load-lock module 40 is disposed between the light emitting element 82 and the light receiving element 83, the light receiving element 83 transmits the information indicating that the detection light is not received to the controller 100. Accordingly, the controller 100 can determine whether or not the wafer W projects from the load-lock module 40.

The controller 100 controls operations of individual components of the processing system 1. FIG. 3 is an explanatory diagram showing an example of the hardware configuration of the controller 100. As shown in FIG. 3, the controller 100 is a computer including a driving device 101, an auxiliary storage device 102, a main storage device 103, a processor 104, an interface device 105, and the like, which are connected to one other by a bus B. A program that implements processing in the controller 100 is provided by a recording medium 106 such as a CD-ROM or the like. When the recording medium 106 storing the program is set in the driving device 101, the program is installed from the recording medium 106 to the auxiliary storage device 102 via the driving device 101. However, the program is not necessarily installed from the recording medium 106, and may be downloaded from another computer via a network. The auxiliary storage device 102 stores required data such as installed programs, recipes, and the like. The main storage device 103 reads out the program from the auxiliary storage device 102 and stores it when there is an instruction for starting the program. The processor 104 executes functions related to the processing system 1 based on the programs stored in the main storage device 103. The interface device 105 is used as a user's input/output device (touch panel, keyboard, mouse, or the like) or as an interface for connection to a network.

### (Pick)

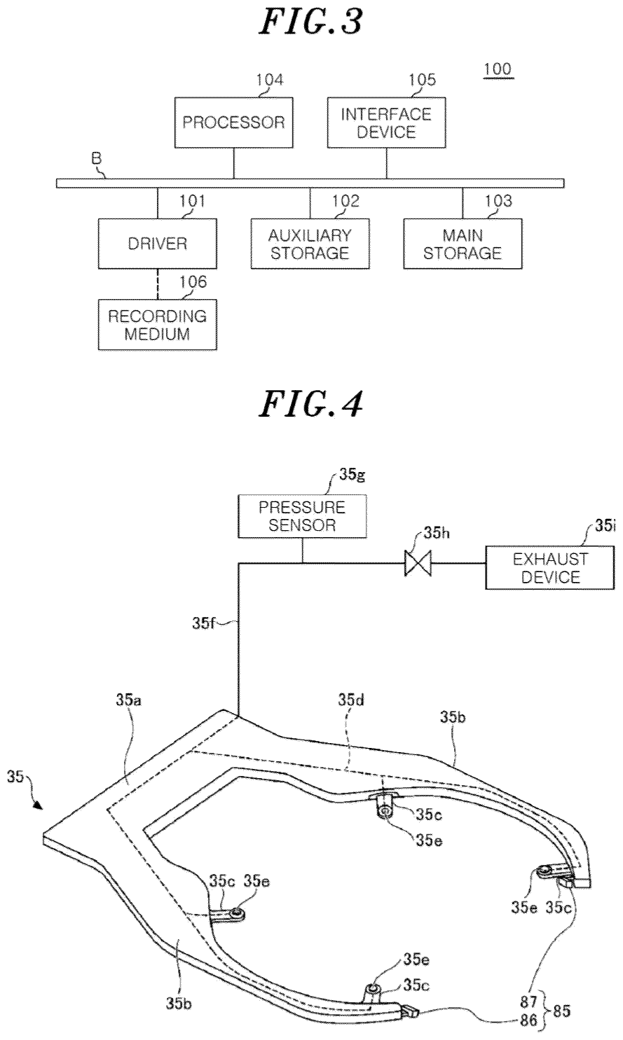

Next, an example of the pick 35 of the atmospheric transfer device 32 will be described with reference to FIG. 4. FIG. 4 shows an example of a schematic configuration of the pick 35.

The pick 35 has a base portion 35a, a pair of tip end extension portions 35b, claw portions 35c, and a suction passage 35d. The base portion 35a is attached to the multi-joint arm 34 (see FIG. 1). The pair of tip end extension portions 35b extend in a substantially arc shape from the base portion 35a in the forward direction of the pick 35, and are symmetrical to each other with the center of the base portion 35a in the width direction interposed therebetween. The claw portions 35c project toward the central portion of the area (hereinafter, referred to as “wafer holding area”) surrounded by the base portion 35a and the tip end extension portion 35b. The four claw portions 35c are spaced apart from each other at intervals along the circumferential direction of the wafer holding area. Suction holes 35e are formed at the upper parts of the claw portions 35c, and the suction holes 35e attract the outer edge of the bottom surface of the wafer W onto the claw portions 35c. The suction passage 35d is disposed in the base portion 35a and the tip end extension portion 35b. The distal end of the suction passage 35d is connected to the suction holes 35e of the claw portions 35c, and the upstream end of the suction passage 35d communicates with a suction line 35f connected to the pick 35.

The suction line 35f is provided with a pressure sensor 35g, which is a pressure detection part, and a valve 35h. The pressure sensor 35g detects a pressure in the suction line 35f, and transmits the detected pressure information to the controller 100. An exhaust device 35i is connected to the downstream side of the valve 35h of the suction line 35f. The exhaust device 35i includes a regulator, a vacuum pump, or the like, and conducts suction from the suction passage 35d and the suction line 35f while adjusting a pressure. The valve 35h is opened during a period from immediately before the atmospheric transfer device 32 receives the wafer W from one module to immediately after the wafer W is placed on another module, and closed during other times. Accordingly, the suction from the suction hole 35e to the wafer W is conducted from immediately before the atmospheric transfer device 32 holds the wafer W to immediately after the wafer W is released.

Further, the atmospheric transfer device 32 includes a mapping sensor (detection part: first detection sensor) 85 at the tip end of the tip end extension portion 35b of the pick 35. The mapping sensor 85 detects an object in the atmospheric transfer module 30 while causing the controller 100 to recognize the coordinates in the atmospheric transfer module 30 as the atmospheric transfer device 32 moves. For example, the mapping sensor 85 detects whether or not a wafer W exists in the substrate storage container 51 placed on the load port 50 and transmits the detection result to the controller 100. Further, the mapping sensor 85 detects the wafer W placed on the stage 42 of the load-lock module 40 and transmits the detection result to the controller 100. Further, the mapping sensor 85 detects whether or not the wafer W is placed on the rotation stage 62 of the aligner 60 and transmits the detection result to the controller 100.

In the present embodiment, the mapping sensor 85 includes a light transmitting portion 86 and a light receiving portion 87 that are arranged to face each other in the horizontal direction. The light transmitting portion 86 is disposed at the tip end of one tip end extension portion 35b of the pick 35, and emits detection light toward the light receiving portion 87. The light receiving portion 87 is disposed at the tip end of the other tip end extension portion 35b of the pick 35, and receives the detection light emitted by the light transmitting portion 86. The light receiving portion 87 of the mapping sensor 85 transmits information indicating that the detection light emitted by the light transmitting portion 86 is not received when the wafer W exists between the light transmitting portion 86 and the light receiving portion 87 to the controller 100. Accordingly, the controller 100 calculates the horizontal position and the height position of the wafer W.

### (Method for Teaching Transfer Device)

The processing system 1 according to one embodiment is basically configured as described above. Next, a teaching method for teaching the transfer position of the wafer W to the atmospheric transfer device 32 after the installation or the maintenance (replacing or repairing components of the atmospheric transfer device 32) of the processing system 1 will be described. In the method for teaching the atmospheric transfer device 32, the controller 100 actually controls the operation of the atmospheric transfer device 32 to set the transfer position of the atmospheric transfer device 32. Hereinafter, a case of setting the transfer position of the stage 42 of the load-lock module 40 will be described. The controller 100 can adopt the same method in the case of teaching the transfer position of the atmospheric transfer device 32 to the substrate storage container 51 of the load port 50 or the aligner 60.

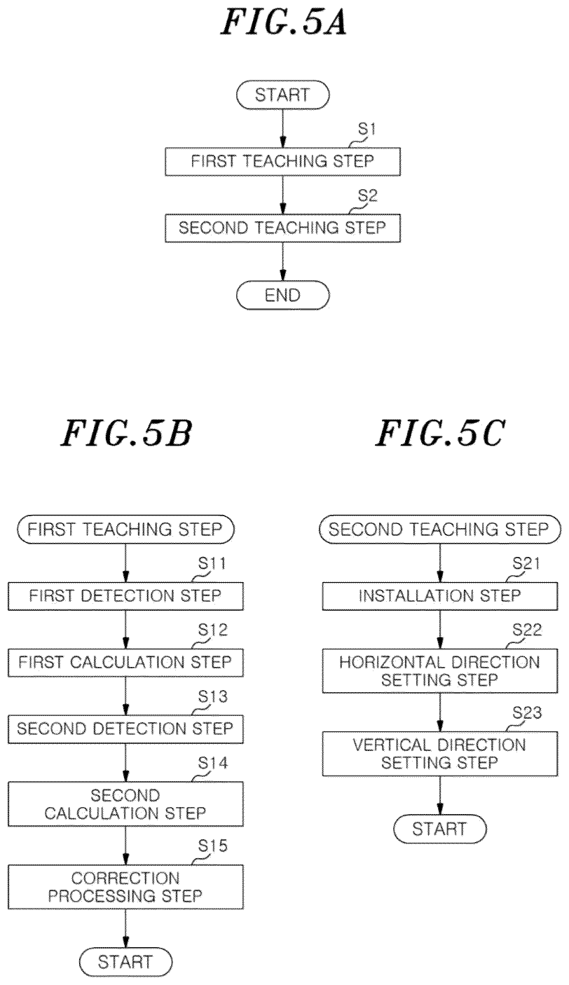

FIG. 5A is a flowchart illustrating a method for teaching the atmospheric transfer device 32 according to an embodiment. FIG. 5B is a flowchart showing an example of a first teaching step S1. FIG. 5C is a flowchart showing an example of a second teaching step S2. As shown in FIG. 5A, the method for teaching the atmospheric transfer device 32 includes the first teaching step S1 and the second teaching step S2. The first teaching step S1 is a step of setting the transfer position of the atmospheric transfer device 32. The second teaching step S2 is executed after the first teaching step S1 and is a step of improving the accuracy by correcting the transfer position of the atmospheric transfer device 32 set in the first teaching step S1.

As shown in FIG. 5B, in the first teaching step S1, the first detection step S11, the first calculation step S12, the second detection step S13, the second calculation step S14, and the correction processing step S15 are performed in that order. The first detection step S11 and the first calculation step S12 are steps for temporarily determining the transfer position in one of the horizontal directions (Y-axis direction) and the vertical direction (Z-axis direction). The second detection step S13 and the second calculation step S14 are steps for temporarily determining the transfer position in the other horizontal direction (X-axis direction). The first detection step S11 and the second detection step S13 correspond to the step (A) of the present disclosure. Specifically, the first detection step S11 corresponds to the step (A-1) of the present disclosure, and the second detection step S13 corresponds to the step (A-2) of the present disclosure. On the other hand, the first calculation step S12 and the second calculation step S14 correspond to the step (B) of the present disclosure.

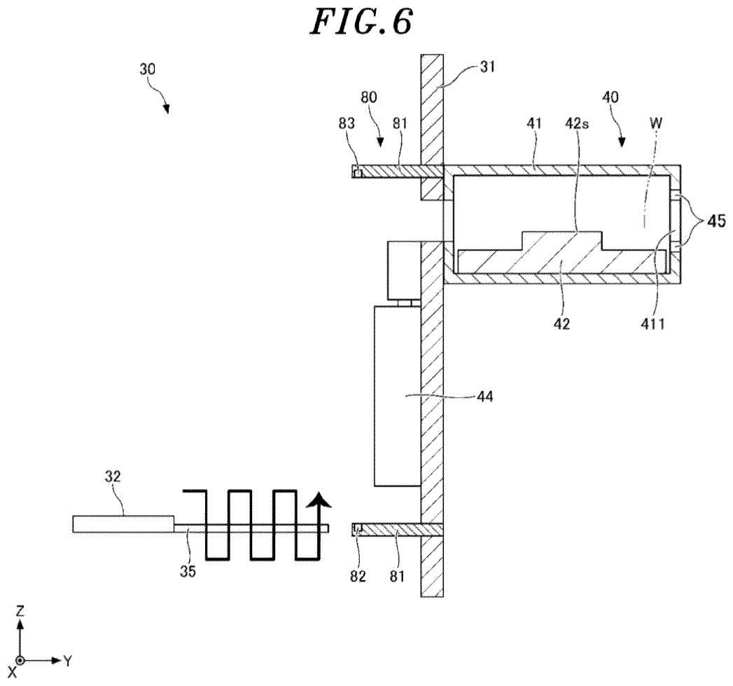

FIG. 6 is an explanatory diagram showing the operation in the first detection step S11. As shown in FIG. 6, in the first detection step S11, the controller 100 moves the atmospheric transfer device 32 toward the load-lock module 40 in the horizontal direction and the vertical direction, and detects the position of the object detection sensor 80 (e.g., the vertically lower protrusion 81) using the mapping sensor 85. The controller 100 temporarily determines the transfer position (Y coordinate and Z coordinate of the atmospheric transfer module 30) of the picks with respect to the stage 42 based on the position in the Y-axis direction (Y coordinate) and the position in the Z-axis direction (Z coordinate) of the mapping sensor 85 at the time of detecting the object detection sensor 80. Then, the controller 100 stores the temporarily determined transfer position in the auxiliary storage device 102, for example. In other words, the information detected by the mapping sensor 85 in the first detection step S11 is information on the position of the stage 42.

Specifically, the controller 100 controls the atmospheric transfer device 32 to repeatedly execute the following operations (a) to (d): (a) operation of sliding the pick 35 at the first height position by a predetermined horizontal pitch along the horizontal direction (Y-axis direction of the atmosphere transfer module 30) to make the pick 35 approach the protrusion 81; (b) operation of lowering the pick 35 from the first height position by a predetermined vertical pitch vertically downward (toward the negative side of the Z-axis direction of the atmospheric transfer module 30) to locate the pick 35 at the second height position; (c) operation of sliding the pick 35 at the second height position by a predetermined horizontal pitch along the horizontal direction (Y-axis direction of the atmospheric transfer module 30) to make the pick 35 to approach the protrusion 81; and (d) operation of raising the pick 35 from the second height position by a predetermined vertical pitch vertically upward (toward the positive side of the Z-axis direction of the atmospheric transfer module 30) to locate the pick 35 at the first height position.

In the above-described operation, the first height position and the second height position (vertical pitch) are automatically set such that the protrusions 81 are disposed therebetween based on the height position of the object detection sensor 80 on the design data stored in the main storage device 103. Further, the horizontal pitch may be set depending on the detection accuracy of the mapping sensor 85 in the horizontal direction, and may be set in units of 5 mm, for example.

During the repeated execution of the above-described operations (a) to (d), the detection light emitted from the light transmitting portion 86 toward the light receiving portion 87 of the mapping sensor 85 is blocked by collision with the protrusion 81. The controller 100 stores the position (Y coordinate of the atmospheric transfer module 30) in an approaching direction of the pick 35 in which the mapping sensor 85 is blocked and the height position (Z coordinate of the atmospheric transfer module 30) in the auxiliary storage device 102. Further, the object detected by the mapping sensor 85 in the first detection step S11 is not limited to the object detection sensor 80 (second detection sensor) of each load-lock module 40, and may be another component of each load-lock module 40. Therefore, the object detection sensor 80 may not protrude into the atmospheric transfer module 30, and may be disposed at the opening of the load-lock module 40, for example.

The stored Y coordinate of the pick 35 is the Y coordinate of the protrusion 81 having the light transmitting element 82, and the distance between the Y coordinate of the protrusion 81 and the Y coordinate of the center of the substrate supporting surface 42s of the load-lock module 40 is predetermined by the hardware design. Therefore, in the first calculation step S12, the controller 100 can calculate the Y coordinate (Y coordinate of the transfer position of the atmospheric transfer device 32) of the center of the substrate supporting surface 42s based on the detected Y coordinate of the protrusion 81. However, the center of the substrate supporting surface 42s of the load-lock module 40 may be deviated depending on the actual installation state of the load-lock module 40. Hence, the controller 100 performs a deviation correction process (correction processing step S15) for eliminating the deviation of the substrate supporting surface 42s of the load-lock module 40 in the teaching method. The deviation correction process will be described in detail later.

Further, the stored Z coordinate of the pick 35 is the Z coordinate of the protrusion 81 having the light transmitting element 82. The distance between the Z coordinate of the protrusion 81 and the Z coordinate of the substrate supporting surface 42s of the load-lock module 40 is also predetermined by the hardware design. Therefore, the controller 100 can calculate the Z coordinate (the Z coordinate of the transfer position of the atmospheric transfer device 32) of the center of the substrate supporting surface 42s based on the detected Z coordinate of the protrusion 81.

After the above first calculation step S12, the controller 100 executes the second detection step S13. However, the second detection step S13 and the second calculation step S14 may be executed before the first detection step S11. In the second detection step S13, the controller 100 detects the pick 35 using the object detection sensor 80 of the load-lock module 40 while moving the pick 35 in the horizontal direction. The controller 100 temporarily determines the transfer position (X coordinate) of the pick 35 with respect to the center of the substrate supporting surface 42s based on the position (X coordinate) in the X-axis direction of the pick 35 at the time of detecting the pick 35. Then, the controller 100 stores the temporarily determined transfer position in the auxiliary storage device 102, for example. In other words, the information detected by the object detection sensor 80 in the second detection step S13 is information on the position of the stage 42.

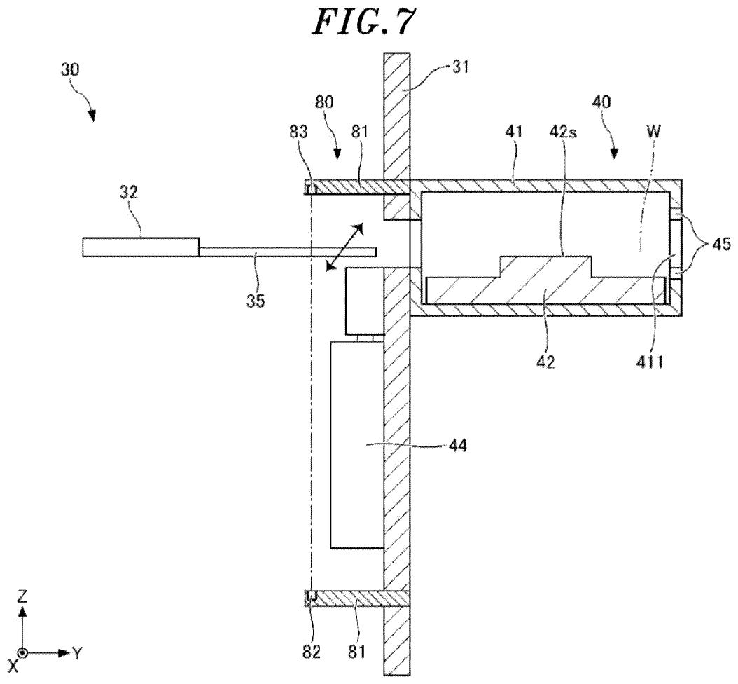

FIG. 7 is an explanatory diagram showing the operation of the atmospheric transfer device 32 in the second detection step S13. As shown in FIG. 7, in the second detection step S13, the controller 100 controls the atmospheric transfer device 32, and moves the pick 35 in the horizontal direction such that a light blocking position and a non-light-blocking position of the detection light emitted from the light emitting element 82 of the object detection sensor 80 toward the light receiving element 83 are included. The light blocking position is, e.g., a position where the base portion 35a or the tip end extension portion 35b of the pick 35 overlaps the object detection sensor 80 in the vertical direction. The non-light-blocking position is, e.g., a position where a hole (not shown) formed through the base portion 35a or the wafer holding area between the pair of tip end extension portions 35b overlaps the object detection sensor 80 in the vertical direction.

In the second detection step S13, the controller 100 obtains the horizontal position (X coordinate of atmospheric transfer module 30) of the pick 35 at the time when the amount of detection light received by the light receiving element 83 shows a predetermined change in the case where the atmospheric transfer device 32 slides the pick 35 in the X-axis direction. For example, the controller 100 moves the pick 35 to a position where the pair of tip end extension portions 35b can overlap the object detection sensor 80 when the pick 35 slides in the X-axis direction based on the Y coordinate of the object detection sensor 80 that is detected in the first detection step S11. Thereafter, the controller 100 moves the pick 35 in the X-axis direction, and detects the X coordinates of the light-blocking position where the pair of tip end extension portions 35b overlap the object detection sensor 80.

The intermediate position between the two X coordinates and the X coordinate of the center of the substrate supporting surface 42s of the load-lock module 40 are preset to coincide with each other by the hardware design. Therefore, in the second calculation step S14, the controller 100 can calculates the X coordinate (the X coordinate of the transfer position of the atmospheric transfer device 32) of the substrate supporting surface 42s of the load-lock module 40 based on the detected X coordinates of the pair of tip end extension portions 35b.

By executing the first detection step S11, the first calculation step S12, the second detection step S13, and the second calculation step S14, the controller 100 temporarily determines the transfer position (three-dimensional position of the X coordinate, the Y coordinate, and the Z coordinate) of the wafer W transferred by the atmospheric transfer device 32. However, the atmospheric transfer module 30 and each load-lock module 40 of the processing system 1 are generally manufactured as separate devices and connected at an installation location such as a factory to construct an integrated system. When the atmospheric transfer module 30 and each load-lock module 40 are installed, each load-lock module 40 may be connected to the atmospheric transfer module 30 in a tilted manner. Further, each load-lock module 40 is connected to the vacuum transfer module 10 in advance (or connected first at the installation position), and thus is hardly deviated with respect to the vacuum transfer module 10.

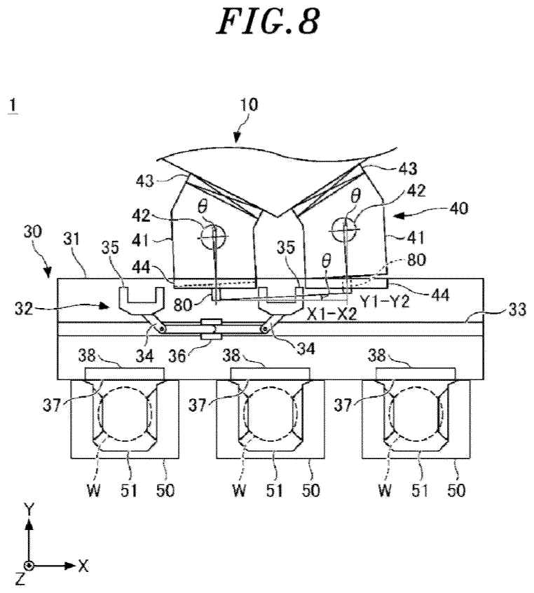

FIG. 8 is a plan view illustrating an installation state in which each load-lock module 40 is tilted with respect to the atmospheric transfer module 30. As shown in FIG. 8, the rectangular atmospheric transfer module 30 has long sides along the X-axis direction and short sides along the Y-axis direction. The X-axis and Y-axis of the pair of load-lock modules 40 are also set based on the center of the substrate supporting surface 42s therein, and the inner pressure variable chamber 41 is manufactured such that the X-axis and the Y-axis become parallel to the X-axis and Y-axis of the atmospheric transfer module 30. When the processing system 1 is installed, basically, the load-lock modules 40 are arranged parallel to the X-axis of the atmospheric transfer module 30 and connected to extend toward the Y-axis.

However, each load-lock module 40 may be connected to the atmospheric transfer module 30 in a tilted manner due to factors such as the flatness or shape of the installation position, the type of connection between modules, and mechanical errors of the atmospheric transfer module 30 or each load-lock module 40. In this case, the X-axis and Y-axis set in each load-lock module 40 are tilted with respect to the X-axis and Y-axis of the atmospheric transfer module 30. Although the tilt angle of each load-lock module 40 is illustrated in an exaggerated manner in FIG. 8, each load-lock module 40 is actually tilted at a very small angle, e.g., less than 1°. Even if each load-lock module 40 is tilted at a very small angle, the center of the substrate supporting surface 42s is deviated from the transfer position recognized by the atmospheric transfer module 30. The deviation of the center of the substrate supporting surface 42s causes deviation when the wafer W is transferred from the atmospheric transfer module 30 to the processing module 20, for example. In other words, the vacuum transfer device 12 of the vacuum transfer module 10 holds and transfers the deviated wafer W from the load-lock module 40 to the processing module 20, so that the wafer W may be placed on the placing table 22 of the processing module 20 while being deviated.

Therefore, in the processing system 1, even when each load-lock module is connected to the atmospheric transfer module 30 in a tilted manner, the deviation correction process for correcting the center (the X coordinate and the Y coordinate of the transfer position of the atmospheric transfer device 32) of the substrate supporting surface 42s of each load-lock module 40 is performed. Hereinafter, the deviation correction process will be describe in detail.

The plurality of load-lock modules 40 are connected to (or integrated with) the vacuum transfer module 10, and thus are installed to be integrally tilted with respect to the atmospheric transfer module 30. Further, the object detection sensors 80 are fixed to the walls of the load-lock modules 40 on the atmospheric transfer module 30 side, and are also integrally tilted with respect to the atmospheric transfer module 30. Therefore, due to the above teaching method, the actual centers of the substrate supporting surfaces 42s are tilted in the same direction and by the same amount with respect to the transfer position (X coordinate and Y coordinate of the coordinate space of the atmospheric transfer module 30) of the substrate supporting surface 42s of the load-lock modules 40 that is recognized by the controller 100. Further, the transfer position of each substrate supporting surface 42s is calculated as a position spaced apart from the Y coordinate at which the mapping sensor 85 detects the object detection sensor 80 by a predetermined distance in the Y-axis direction.

In other words, the direction and amount of deviation of the actual center of the substrate supporting surface 42s with respect to the transfer position recognized by the left load-lock module 40, and the direction and amount of deviation of the actual center of the substrate supporting surface 42s with respect to the transfer position recognized by right the load-lock module 40 are the same. Therefore, in the deviation correction process, the controller 100 can calculate the tilt angle of each load-lock module 40 using the previously recognized X and Y coordinates of the plurality of (two) object detection sensors 80.

Specifically, the X coordinates of the two object detection sensors 80 (hereinafter, the X coordinate of the transfer position of the left load-lock module is referred to as “X1” and the X coordinate of the transfer position of the right load-lock module 40 is referred to as “X2”) are spaced apart from each other by the installation gap of the load-lock modules 40. Further, when each load-lock module 40 is tilted, the Y coordinates of the two object detection sensors 80 (hereinafter, the Y coordinate of the transfer position of the left load-lock module is referred to as “Y1” and the Y coordinate of the transfer position of the right load-lock module 40 is referred to as “Y2”) are deviated from each other. The gap between X1 and X2 in the X-axis direction and the gap between Y1 and Y2 in the Y-axis direction of the two object detection sensors 80 can form a right triangle according to the tilt angle of each load-lock module 40.

Therefore, the tilt angle θ of each load-lock module 40 with respect to the atmospheric transfer module 30 can be calculated based on the cotangent of the ratio of the gap between the X coordinates to the gap between the Y coordinates. Specifically, the controller 100 calculates the tilt angle θ using the following Eq. (1).

$$θ = {tan}^{- 1} ( Y 2 - Y 1 ) / ( X 2 - X 1 ) \qquad Eq . ( 1 )$$

After the detection of the detection position (X coordinate, Y coordinate) of each object detection sensor 80 in the horizontal direction, the controller 100 calculates the tilt angle θ using the above Eq. (1) and the X coordinate and Y coordinate of each object detection sensor 80 in the deviation correction process. Then, the controller 100 corrects the horizontal component (X coordinate, Y coordinate) of the recognized transfer position by adding the tilt angle θ to the transfer position of the load-lock module 40. Accordingly, the controller 100 can accurately correct the transfer position of the stage 42 of each load-lock module to the actual center of the substrate supporting surface 42s of the load-lock module 40.

Further, in the case of detecting the horizontal detection position of each object detection sensor 80 (or calculating the tilt angle θ), the controller 100 may determine whether or not the detected X coordinate or Y coordinate (or the tilt angle θ) is deviated by more than a predetermined threshold. In this case, if the X coordinate or the Y coordinate of any one of the object detection sensors 80 is less than the predetermined threshold, the controller 100 continues the teaching operation of the atmospheric transfer device 32. On the other hand, if the X coordinate or the Y coordinate of any of the object detection sensors 80 is deviated by more than the predetermined threshold, the controller 100 notifies an error using the interface device 105 or the like, and stops the processing flow of the teaching method. Accordingly, when large deviation occurs in the load-lock module 40, the processing system 1 can notify a user of the deviation at an early stage and refrain from performing the teaching method.

Further, the controller 100 may extract the Z coordinates of the transfer positions of the substrate supporting surfaces 42s of the plurality of load-lock modules 40, and calculate the tilt angle of each load-lock module 40 in the Z axis direction based on the deviation of the Z coordinates. The tilt angle of the entire three-dimensional coordinates of each load-lock module 40 can be calculated using the calculated tilt angle of each load-lock module 40 in the Z-axis direction, and the correction accuracy of the transfer position of the substrate supporting surface 42s can be further improved using the calculated tilt angle.

Referring back to FIG. 5A, the transfer position for each load-lock module is set in the first teaching step S1 and, then, the controller 100 proceeds to the second teaching step S2. The second teaching step S2 in which the wafer W is actually transferred and the transfer position of each load-lock module 40 set in the first teaching step S1 is corrected corresponds to the step C of the present disclosure. In the second teaching step, the controller 100 sequentially executes an installation step S21 for a wafer W, a horizontal direction setting step S22, and a vertical direction setting step S23, as shown in FIG. 5C.

In the installation step S21, the controller 100 controls the operation of the atmospheric transfer device 32, and transfers the wafer to the transfer position (X coordinate, Y coordinate, Z coordinate) of each load-lock module 40 recognized in the first teaching step S1. Accordingly, the wafer W is placed on the substrate supporting surface 42s of each load-lock module 40. Thereafter, the controller 100 operates the vacuum transfer device 12 of the vacuum transfer module 10 to receive the wafer W from each load-lock module 40.

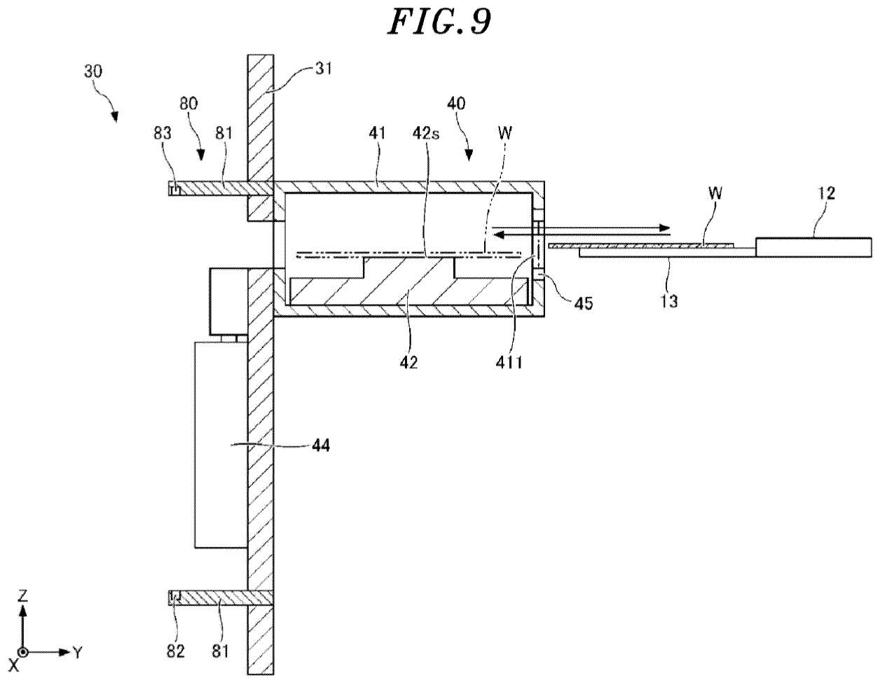

FIG. 9 is an explanatory diagram showing the operation of the vacuum transfer device 12 in the installation step S21. As shown in FIG. 9, the vacuum transfer device 12 retreats from each load-lock module 40 to allow the wafer W to pass through the position detection sensor 45 of the load-lock module 40. By detecting the position of the outer edge of the wafer W using the position detection sensor 45, the controller 100 can recognize the center of the wafer W. Therefore, the controller 100 transfers the wafer W held by the vacuum transfer device 12 to the substrate supporting surface 42s of the load-lock module 40 again based on the recognized center of the wafer W. In this case, the controller 100 places the wafer W such that the recognized center of the wafer W and the center of the substrate supporting surface 42s coincide with each other. By placing the wafer W on the substrate supporting surface 42s of each load-lock module 40 in the above-described manner, it is possible to prevent the wafer W from being deviated with respect to the substrate supporting surface 42s.

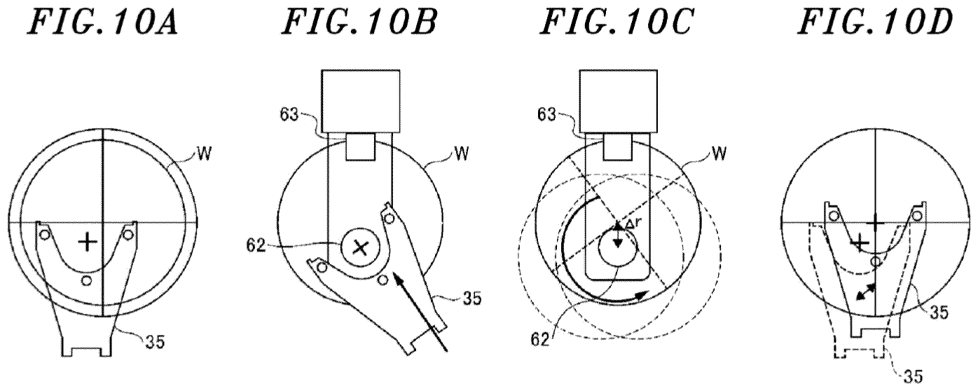

The controller 100 executes the horizontal direction setting step S22 after the installation step S21. FIGS. 10A to 10D explain an example of the horizontal direction setting step S22.

First, the controller 100 unloads the wafer W after the installation step S21 from the load-lock module 40 using the atmospheric transfer device 32 (see FIG. 10A). Next, the controller 100 loads the unloaded wafer W into the aligner 60, and places the wafer W on the rotation stage 62 of the aligner 60 (see FIG. 10B). Thereafter, the controller 100 rotates the wafer W placed on the rotation stage 62, and calculates the amount of eccentricity Ar and the direction of eccentricity of the wafer W based on the value detected by the optical sensor 63 at the time of rotating the wafer W (see FIG. 10C). Finally, the controller 100 corrects the transfer position based on the calculated amount of eccentricity Ar and the calculated direction of eccentricity (see FIG. 10D). For example, the controller 100 corrects the horizontal component of the transfer position in a direction opposite to the direction of eccentricity by the calculated amount of eccentricity Ar to set a new transfer position. Further, in FIG. 10D, the transfer position before the correction is indicated by a dashed line, and the transfer position after the correction is indicated by a solid line.

Due to the horizontal direction setting step S22, the accuracy of the horizontal transfer position of the atmospheric transfer device 32 is improved.

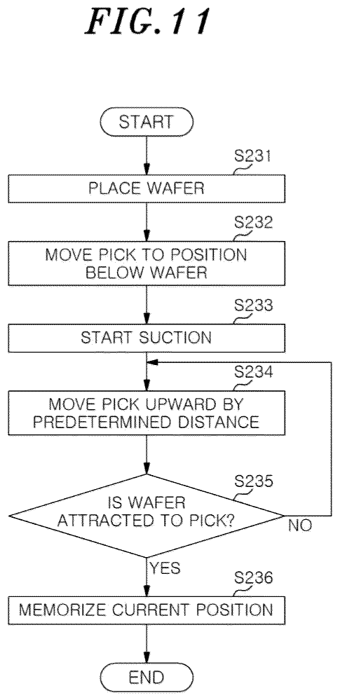

After the horizontal direction setting step S22, the controller 100 executes the vertical direction setting step S23 for determining the vertical transfer position of the pick 35. FIG. 11 is a flowchart for explaining the vertical direction setting step S23 for determining the vertical transfer position. The vertical direction setting step S23 includes steps S231 to S236.

In step S231, a user places the wafer W on the substrate supporting surface 42s of the load-lock module 40.

In step S232, the controller 100 moves the pick 35 of the atmospheric transfer device 32 to a position below the wafer W based on the vertical transfer position temporarily determined in the first teaching step S1 and the horizontal transfer position determined in the horizontal direction setting step S22.

In step S233, the controller 100 starts suction in the suction passage 35d and the suction line 35f by opening the valve 35h disposed in the suction line 35f. However, the timing to start the suction in the suction passage 35d and the suction line 35f is not limited thereto. For example, the suction may be started before the pick 35 is moved to a position below the wafer W, or while the pick 35 is moving to a position below the wafer W.

In step S234, the controller 100 moves the pick 35 upward by a predetermined distance (e.g., 0.1 mm) in a state where the suction passage 35d and the suction line 35f are sucked, and then stops the pick 35. Accordingly, the distance between the top surface of the pick 35 and the bottom surface of the wafer W becomes short.

In step S235, the controller 100 determines whether or not the wafer W is attracted to the pick 35. For example, the controller 100 determines whether or not the wafer W is attracted to the pick 35 based on whether or not the attraction pressure detected by the pressure sensor 35g has reached a predetermined threshold or less within a predetermined period of time. Specifically, when the attraction pressure has reached a predetermined threshold value or less within the predetermined period of time, the controller 100 determines that the wafer W is attracted to the pick 35. On the other hand, when the attraction pressure had not reached the predetermined threshold or less within the predetermined period of time, the controller 100 determines that the wafer W is not attracted to the pick 35. The predetermined period of time may be, e.g., time required until the attraction pressure detected by the pressure sensor 35g becomes substantially constant. For example, the controller 100 may determine whether or not the wafer W is attracted to the pick 35 based on whether or not the change in the attraction pressure at the time when the pick 35 is moved upward by a predetermined distance with respect to the attraction pressure at the time when the pick 35 is positioned below the wafer W is greater than or equal to a predetermined threshold. Specifically, when the change in the attraction pressure is greater than or equal to the predetermined threshold, the controller 100 determines that the wafer W is attracted to the pick 35. On the other hand, when the change in the attraction pressure is less than the predetermined threshold, the controller 100 determines that the wafer W is not attracted to the pick 35. For example, when the atmospheric transfer device 32 has a controller capable of determining whether or not the wafer W is attracted to the pick 35 based on the attraction pressure, the controller 100 may determine whether or not the wafer W is attracted to the pick 35 based on the determination result of the controller. Specifically, when the controller determines that the wafer W is attracted to the pick 35, the controller 100 receives the determination result of the controller and determines that the wafer W is attracted to the pick 35. On the other hand, when the controller determines that the wafer W is not attracted to the pick 35, the controller 100 receives the determination result of the controller and determines that the wafer W is not attracted to the pick 35.

If it is determined in step S235 that the wafer W is not attracted to the pick 35, the controller 100 determines that the backside of the wafer W is not in contact with the upper surface of the pick 35, and returns to step S234. In other words, the controller 100 intermittently moves the pick 35 upward until the wafer W is attracted to the pick 35. On the other hand, if it is determined in step S235 that the wafer W is attracted to the pick 35, the controller 100 determines that the backside of the wafer W is in contact with the upper surface of the pick 35, and proceeds to step S236.

In step S236, the position of the pick 35 at the time when it is determined in step S235 that the backside of the wafer W is in contact with the upper surface of the pick 35 is stored, as the vertical transfer position of the pick 35, in the auxiliary storage device 102. Then, the processing is ended.

Due to the above steps S231 to S236, the atmospheric transfer device 32 can set the vertical component of the transfer position. In the vertical direction setting step S23, the vertical transfer position of the atmospheric transfer device 32 is determined based on the attraction pressure at the time when the pick 35 that conducts suction and holding of the wafer W is moved from a position below the wafer W to a position above the wafer W. As a result, an operator does not need to visually detect the position, which makes it possible to suppress variation in the teaching accuracy of the atmospheric transfer device 32 in the vertical direction depending on an operator's skill level.

As described above, the processing system 1 can improve the accuracy of the transfer position of each load-lock module 40 of the atmospheric transfer device 32 by executing the first teaching step S1 and the second teaching step S2. In particular, in the first teaching step S1, the controller 100 calculates the tilt angle θ of each load-lock module 40 with respect to the atmospheric transfer module 30 based on information on the positions of the plurality of stages 42, and sets the transfer positions of the plurality of stages 42. Accordingly, the correction for the tilt angle θ of the load-lock module 40 is completed before the execution of the second teaching step S2, and the processing system 1 may execute the second teaching step S2 based on the transfer position in which the deviation of the stage 42 of each load-lock module 40 has been eliminated. Hence, the processing system 1 can further improve the accuracy of transferring the wafer W by the atmospheric transfer device 32.

Further, the processing system 1 can simply obtain the transfer position (information on the position of the support) of the stage 42 using, as detection parts, the mapping sensor 85 of the atmospheric transfer device 32 and the object detection sensor 80 of the load-lock module 40. Further, the processing system 1 detects the position of the object detection sensor 80 using the mapping sensor while moving the atmospheric transfer device 32, or detects the atmospheric transfer device 32 using the object detection sensor 80. Accordingly, the controller 100 can easily obtain the transfer position of the stage 42.

Further, the processing system 1 can effectively detect the transfer position in the three-dimensional direction of the stage 42 by detecting the Y coordinate and the Z coordinate of the stage 42 in the first detection step S11, and detecting the X coordinate of the stage 42 in the second detection step S13. The processing system 1 can efficiently detect the position of the object detection sensor 80 using the mapping sensor 85 by repeating the vertical operation and the horizontal operation in the first detection step S11. Further, the processing system 1 can efficiently detect the position of the atmospheric transfer device 32 using the object detection sensor 80 by sliding the atmospheric transfer device 32 along the X-axis direction in the second detection step S13.

Further, the processing system 1 according to the present embodiment does not necessarily have the above-described configuration, and may have various modifications. For example, in the above embodiment, an example in which the processing system 1 transfers a substrate (wafer W) as an object to be transferred has been described. However, the object to be transferred by the processing system 1 is not limited to a substrate. For example, even when the processing system 1 has a configuration in which a ring (an edge ring (also referred to as “focus ring”), a cover ring, or the like) used in the processing module 20 is transferred, the teaching of the transfer position can be performed by the above-described configuration.

The above-described embodiments include, e.g., the following aspects.

### APPENDIX 1

A processing system comprising:
a transfer module having therein a transfer device configured to transfer an object to be transferred;
a plurality of load-lock modules connected to the transfer module, each having therein a support that supports the object to be transferred;
a detection part disposed in the transfer device and the plurality of load-lock modules and detecting an object during movement of the transfer device; and
a controller configured to process a detection result obtained by the detection part and control an operation of the transfer device,
wherein the controller controls:
(A) acquiring information on positions of the supports in the plurality of load-lock modules from a detection result of the object detected by the detection part while moving the transfer device; and
(B) calculating, after said (A), tilt angles of the plurality of load-lock modules with respect to the transfer module based on the acquired information on the positions of the plurality of supports, and setting the positions of the plurality of supports using the calculated tilt angles.

### APPENDIX 2

The processing system of Appendix 1, wherein the detection part includes:
a first detection sensor disposed in the transfer device and detecting an object in the transfer module while causing the controller to recognize coordinates in the transfer module as the transfer device moves; and
a second detection sensor detecting the object to be transferred or the transfer device in each of the plurality of load-lock modules.

### APPENDIX 3

The processing system of Appendix 2, wherein in said (A), the controller detects, as information on the positions of the supports, the position of the second detection sensor using the first detection sensor while moving the transfer device, or the transfer device that is moving using the second detection sensor.

### APPENDIX 4

The processing system of Appendix 3, wherein in said (A), the controller controls:

(A-1) acquiring, as information on the positions of the supports, a Z coordinate of the second detection sensor in the vertical direction and a Y coordinate in a direction in which the transfer device approaches to the plurality of load-lock modules.

### APPENDIX 5

The processing system of Appendix 4, wherein in said (A-1), the controller controls to:
repeat an operation of sliding the transfer device by a predetermined horizontal pitch at a first height position, an operation of lowering the transfer device from the first height position by a predetermined vertical pitch and placing the transfer device at a second height position, an operation of sliding the transfer device by a predetermined horizontal pitch at the second height position, and raising the transfer device from the second height position by a predetermined vertical pitch and placing the transfer device at the first height position, and
detect the second detection sensor using the first detection sensor.

### APPENDIX 6

The processing system of any one of Appendices 3 to 5, wherein in said (A), the controller controls:

(A-2) acquiring an X coordinate in a direction in which the plurality of load-lock modules are arranged.

### APPENDIX 7

The processing system of Appendix 6, wherein in said (A-2), the controller detects the transfer device using the second detection sensor while sliding the transfer device in the direction in which the plurality of load-lock modules are arranged.

### APPENDIX 8

The processing system of any one of Appendices 1 to 7, wherein the controller is configured to recognize the X coordinate, the Y coordinate, and the Z coordinate, which are coordinates of axes intersecting with each other in the transfer module, as the positions of the supports, and
in said (B), the tilt angles are calculated based on a cotangent of a ratio of a gap between the X coordinates of the plurality of supports to a gap between the Y coordinates of the plurality of supports.

### APPENDIX 9

The processing system of Appendix 8, wherein in said (B), the controller calculates the tilt angles of the plurality of load-lock modules in the Z-axis direction based on deviation of the Z coordinates of the plurality of supports.

### APPENDIX 10

A processing system according to any one of Appendices 1 to 9, wherein the controller further controls:
(C) transferring, after said (B), the object to be transferred in the transfer module, detecting the position of the object to be transferred by sensors disposed in the plurality of load-lock modules and/or an aligner connected to the transfer module, and correcting the positions of the plurality of supports based on the detection result.

### APPENDIX 11

A processing system of any one of Appendices 1 to 10, wherein the controller determines whether or not the information on the positions of the supports detected in said (A) is deviated by more than a predetermined threshold, continues the teaching operation of the transfer device when the information on the positions of the supports is less than the predetermined threshold, and notifies an error when the information on the positions of the supports is deviated by more than the predetermined threshold.

### APPENDIX 12

A teaching method for teaching positions of a plurality of supports to a transfer device in a processing system, wherein the processing system includes: a transfer module having therein the transfer device configured to transfer an object to be transferred;
a plurality of load-lock modules connected to the transfer module, each having therein the support that supports the object to be transferred; and
a detection part disposed in the transfer device and the plurality of load-lock modules and detecting an object during movement of the transfer device,
the teaching method comprising:
(A) acquiring information on the positions of the supports in the plurality of load-lock modules from a detection result of the object detected by the detection part while moving the transfer device; and
(B) calculating, after said (A), tilt angles of the plurality of load-lock modules with respect to the transfer module based on the information on the detected positions of the plurality of supports, and setting the positions of the plurality of supports using the calculated tilt angles.

The processing system 1 and the teaching method of the above-described embodiments are illustrative in all respects and are not restrictive. The embodiments may be variously modified and improved without departing from the scope of the appended claims and the gist thereof. The above-described embodiment may include other configurations without contradicting each other and may be combined without contradicting each other.

1. A processing system comprising:
a transfer module having therein a transfer device configured to transfer an object to be transferred;
a plurality of load-lock modules connected to the transfer module, each having therein a support that supports the object to be transferred;
a detection part disposed in the transfer device and the plurality of load-lock modules and detecting an object during movement of the transfer device; and
a controller configured to process a detection result obtained by the detection part and control an operation of the transfer device,
wherein the controller controls:
(A) acquiring information on positions of the supports in the plurality of load-lock modules from a detection result of the object detected by the detection part while moving the transfer device; and
(B) calculating, after said (A), tilt angles of the plurality of load-lock modules with respect to the transfer module based on the acquired information on the positions of the plurality of supports, and setting the positions of the plurality of supports using the calculated tilt angles.

2. The processing system of claim 1, wherein the detection part includes:
a first detection sensor disposed in the transfer device and detecting an object in the transfer module while causing the controller to recognize coordinates in the transfer module as the transfer device moves; and
a second detection sensor detecting the object to be transferred or the transfer device in each of the plurality of load-lock modules.

3. The processing system of claim 2, wherein in said (A), the controller detects, as information on the positions of the supports, the position of the second detection sensor using the first detection sensor while moving the transfer device, or the transfer device that is moving using the second detection sensor.

4. The processing system of claim 3, wherein in said (A), the controller controls:
(A-1) acquiring, as information on the positions of the supports, a Z coordinate of the second detection sensor in the vertical direction and a Y coordinate in a direction in which the transfer device approaches to the plurality of load-lock modules.

5. The processing system of claim 4, wherein in said (A-1), the controller controls to:
repeat an operation of sliding the transfer device by a predetermined horizontal pitch at a first height position, an operation of lowering the transfer device from the first height position by a predetermined vertical pitch and placing the transfer device at a second height position, an operation of sliding the transfer device by a predetermined horizontal pitch at the second height position, and raising the transfer device from the second height position by a predetermined vertical pitch and placing the transfer device at the first height position, and
detect the second detection sensor using the first detection sensor.

6. The processing system of claim 3, wherein in said (A), the controller controls:
(A-2) acquiring an X coordinate in a direction in which the plurality of load-lock modules are arranged.

7. The processing system of claim 6, wherein in said (A-2), the controller detects the transfer device using the second detection sensor while sliding the transfer device in the direction in which the plurality of load-lock modules are arranged.

8. The processing system of claim 1, wherein the controller is configured to recognize the X coordinate, the Y coordinate, and the Z coordinate, which are coordinates of axes intersecting with each other in the transfer module, as the positions of the supports, and
in said (B), the tilt angles are calculated based on a cotangent of a ratio of a gap between the X coordinates of the plurality of supports to a gap between the Y coordinates of the plurality of supports.

9. The processing system of claim 2, wherein the controller is configured to recognize the X coordinate, the Y coordinate, and the Z coordinate, which are coordinates of axes intersecting with each other in the transfer module, as the positions of the supports, and
in said (B), the tilt angles are calculated based on a cotangent of a ratio of a gap between the X coordinates of the plurality of supports to a gap between the Y coordinates of the plurality of supports.

10. The processing system of claim 8, wherein in said (B), the controller calculates the tilt angles of the plurality of load-lock modules in the Z-axis direction based on deviation of the Z coordinates of the plurality of supports.

11. The processing system of claim 9, wherein in said (B), the controller calculates the tilt angles of the plurality of load-lock modules in the Z-axis direction based on deviation of the Z coordinates of the plurality of supports.

12. A processing system according to claim 1, wherein the controller further controls:
(C) transferring, after said (B), the object to be transferred in the transfer module, detecting the position of the object to be transferred by sensors disposed in the plurality of load-lock modules and/or an aligner connected to the transfer module, and correcting the positions of the plurality of supports based on the detection result.

13. A processing system according to claim 2, wherein the controller further controls:
(C) transferring, after said (B), the object to be transferred in the transfer module, detecting the position of the object to be transferred by sensors disposed in the plurality of load-lock modules and/or an aligner connected to the transfer module, and correcting the positions of the plurality of supports based on the detection result.

14. A processing system of claim 1, wherein the controller determines whether or not the information on the positions of the supports detected in said (A) is deviated by more than a predetermined threshold, continues the teaching operation of the transfer device when the information on the positions of the supports is less than the predetermined threshold, and notifies an error when the information on the positions of the supports is deviated by more than the predetermined threshold.

15. A processing system of claim 2, wherein the controller determines whether or not the information on the positions of the supports detected in said (A) is deviated by more than a predetermined threshold, continues the teaching operation of the transfer device when the information on the positions of the supports is less than the predetermined threshold, and notifies an error when the information on the positions of the supports is deviated by more than the predetermined threshold.

16. A teaching method for teaching positions of a plurality of supports to a transfer device in a processing system, wherein the processing system includes:
a transfer module having therein the transfer device configured to transfer an object to be transferred;
a plurality of load-lock modules connected to the transfer module, each having therein the support that supports the object to be transferred; and
a detection part disposed in the transfer device and the plurality of load-lock modules and detecting an object during movement of the transfer device,
the teaching method comprising:
(A) acquiring information on the positions of the supports in the plurality of load-lock modules from a detection result of the object detected by the detection part while moving the transfer device; and
(B) calculating, after said (A), tilt angles of the plurality of load-lock modules with respect to the transfer module based on the information on the detected positions of the plurality of supports, and setting the positions of the plurality of supports using the calculated tilt angles.
